(19) United States
(12) Patent Application Publication
(10) Pub. No.: US 2008/0286962 A1
(43) Pub. Date: Nov. 20, 2008

(54) METHOD FOR FABRICATING METAL PAD

(75) Inventor: Min-Hyung LEE, Seoul (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 12/122,313

(22) Filed: May 16, 2008

(30) Foreign Application Priority Data
May 18, 2007 (KR) 10-2007-0048559

(51) Int. Cl. H01L 21/4763

(52) U.S. Cl. 438/631; 257/E21.576

(57) ABSTRACT

A method for fabricating a metal pad is disclosed. The fabrication method includes the step of selectively etching a wire insulation film formed on a semiconductor substrate to form a pattern, such as a dual damascene pattern, having plural vias in one trench. A metal film is deposited to fill the pattern and an insulation film is formed on the metal film. Further, the method includes removing the insulation film and the metal film to expose a surface of the wire insulation film to thereby form a metal pad and via contacts.

### CROSS-REFERENCE TO RELATED APPLICATION

This application claims priority to Korean Application No. 10-2007-0048559, filed on May 18, 2007, which is incorporated herein by reference in its entirety.

### BACKGROUND

1. Field of the Invention

Embodiments of the present invention relate to a semiconductor fabrication method, and more specifically, to a method for fabricating a metal pad.

2. Background of the Invention

Typically, a bonding pad has a wiring structure formed on an integrated circuit to provide a contact surface between an outer pin lead and an inner circuit of an integrated circuit package. Usually, a bonding wire is used to provide the electric contact between the pin and the bonding pad. During assembly, a position calibrator (or similar device) is used to lower and position the bonding wire for attachment with the bonding pad. This usually imposes a mechanical stress on the bonding wire and the bonding pad, which stress can result in cracks or voids being formed on a lower insulation film under the bonding pad.

One technique to resolve such a problem involves the formation of a bonding pad over upper and lower metal pads 100 and 102, and providing plural metal vias 104 between the upper and lower metal pads 100 and 102 to mitigate the stress. As is illustrated in FIG. 1, the plural metal vias 104 are formed on an interlayer insulation film 106 made at the upper and lower metal pads 100 and 102, each of which is gap filled with metal substance.

However, this technique is not without problems. For example, when forming the bonding pad using the upper and lower metal pads 100 and 102 and the plural metal vias 104, the stress becomes concentrated to lower portions of the metal vias 104. Under the influence of this stress, blanks of a metal plating film inside the lower metal pad 100 are concentrated in lower portions of the metal vias 104, which can result in the formation of voids, examples of which are denoted at 108. As more metal vias 104 are formed on the interlayer insulation film 106, such voids 108 can be connected to each other and thereby separate the lower metal pad 100 and the metal vias 104 from each other, which can then cause defects in a semiconductor chip.

### SUMMARY OF EXAMPLE EMBODIMENTS

In general, example embodiments of the of the present invention relate to methods for fabricating a metal pad in a manner so as to minimize or prevent connection defects between via contacts and the metal pad. In this way, the bonding force between a via contact and a metal pad is improved.

In accordance with one example embodiment, a fabrication method includes the step of selectively etching a wire insulation film formed on a semiconductor substrate to form a pattern, such as a dual damascene pattern, having plural vias in one trench. A metal film is deposited to fill the pattern. An insulation film is formed on the metal film, which produces stress between the metal film and the insulation film such that voids are formed inside the metal film or between the metal film and the insulation film. The voids created from the stress are concentrated at the upper portion of the metal film. The insulation film and the metal film can then be removed to expose a surface of the wire insulation film and thereby form metal pad and via contacts. Since this also results in the removal of the void-containing region, defects between the via contacts and the metal pad are largely prevented, thereby improving the bonding force between the vias and the metal pad. This can also minimize the occurrence of cracks during later manufacturing processes, and minimize defects in a resulting semiconductor device.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

Additional features will be set forth in the description which follows, and in part will be obvious from the description, or may be learned by the practice of the teachings herein. Features of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

The above and other advantages and features of the present invention will become apparent from the following description of example embodiments, given in conjunction with the accompanying drawings, in which:

FIG. 1 is a cross-sectional view showing the structure of a general multilayer metal pad; and

FIGS. 2A to 2G illustrate one example of the process steps that can be used to fabricate a metal pad illustrated by making reference to cross-sectional views of a metal pad during the fabrication process.

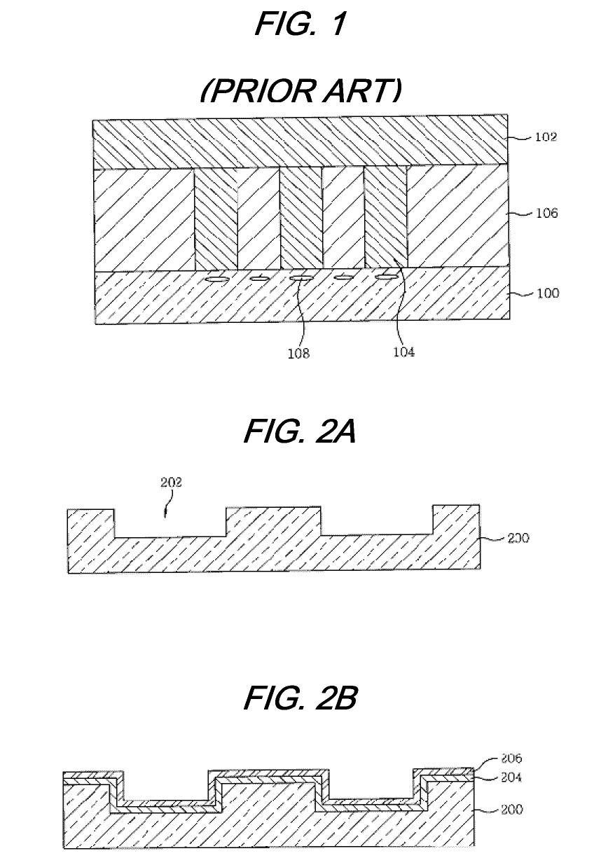

### DETAILED DESCRIPTION OF EXAMPLE EMBODIMENTS

Hereinafter, a method for fabricating a metal pad in accordance with one or more example embodiments of present invention will be described in detail with reference to the accompanying drawings. In the following detailed description of the example embodiments, reference is made to the accompanying drawings that show, by way of illustration, specific embodiments of the invention. In the drawings, like numerals describe substantially similar components throughout the several views. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

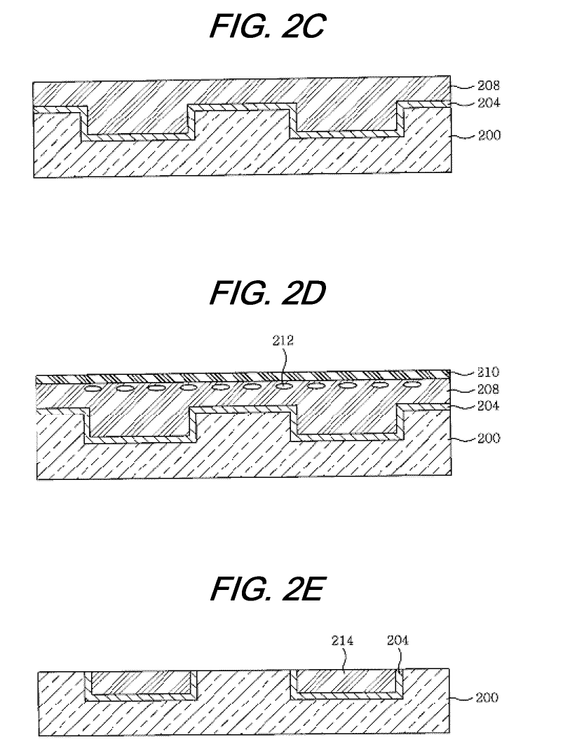

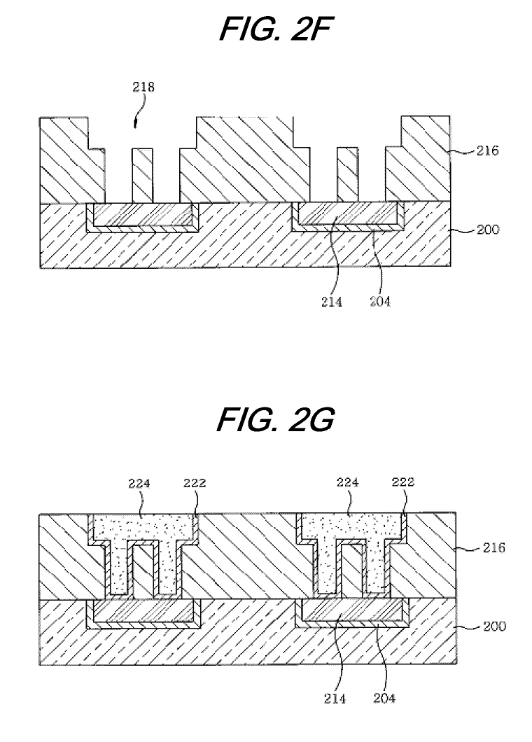

Reference will be made to FIGS. 2A to 2G, which together illustrate process cross-sectional views of one example of the sequential steps that can be used in the fabrication of a metal pad.

Referring first to FIG. 2A, a first wire insulation film 200 is etched selectively to form a lower metal pad region 202. In an illustrated embodiment, the lower metal pad region 202 is formed by coating an upper portion of the first wire insulation film 200 with photoresist, and then carrying out the exposure and development process to obtain a photoresist pattern. Next, the first wire insulation film 200 is etched to a designated depth following the photoresist pattern to form the lower metal pad region 202 in a trench shape. Formed on the first wire insulation film 200 are a plurality of vias (not shown) connected to the lower metal pad region 202.

Reference is next made to FIG. 2B, which illustrates how a first metal barrier film 204 and a first metal seed film 206 are formed on the resulting structure. The first metal barrier film 204 and the first metal seed film 206 can be formed by using a copper material, although other materials could be used.

As is next shown in FIG. 2C, the lower metal pad region 202 is substantially filled. For example, in an illustrated embodiment the first metal seed film 206 is plated by an electroplating method to form a metal plating film 208. In this way, the lower metal pad region 202 is substantially filled.

Next, an insulation film 210 is disposed on the metal plating film 208. In the example of FIG. 2D, a thin insulation film 210 can be formed on the metal plating film 208 by using, for example, a PECVD (Plasma Enhanced Chemical Vapor Deposition) method. In an example embodiment, the insulation film 210 is formed in the absence of oxygen. Examples of a suitable film material include, without limitation, SiN and SiC.

In one example embodiment, the insulation film 210 is formed on the metal plating film 208 to a thickness of about 100 to 10000 Å, and at a temperature of about 100 to 500° C. As the insulation film 210 is formed, stress is produced between the metal plating film 208 and the insulation film 210, such that voids 212 are formed inside the metal plating film 208, or between the metal plating film 208 and the insulation film 210.

As is denoted in FIG. 2E, the insulation film 210, the metal plating film 208 and the first metal barrier film 204 are removed in part to expose the surface of the first wire insulation film 200, thereby forming a lower metal pad 214. Although other techniques might be used, in one example embodiment a CMP (Chemical Mechanical Polishing) process that uses the top surface of the first wire insulation 200 as the polishing endpoint is carried out to remove the insulation film 210, the metal plating film 208, and the first metal barrier film 204. Such a CMP process can remove the voids 212 formed due to stress between the metal plating film 208 and the insulation film 210.

It will be appreciated that although in the example embodiment the CMP process is be performed immediately after the formation of the insulation film 210, the CMP process could also be performed after the formation of the insulation film 210 and then followed by a heat treatment process. The heat treatment process could be carried out under a gas atmosphere of nitrogen (N₂), argon (Ar) or hydrogen (H₂) or a mixed gas thereof at a temperature of about 100 to 500° C. for five hours or less.

Referring next to FIG. 2F, in an illustrated embodiment a second thick wire insulation film 216 is formed on the resulting structure, and then etched to form plural vias and a trench (upper metal pad region) having plural vias connected to the lower metal pad 202 are formed. In the illustrated embodiment, the pattern is in the form of a dual damascene pattern, generally denoted at 218. In an example embodiment, the vias that are formed to connect the lower metal pad 202 and the upper metal pad have a density of about 1 to 50% of the area of the lower metal pad 202, and the number of vias is adjustable based on the density.

As is shown in FIG. 2G, a second metal barrier film (not shown—similar to FIG. 2B) and a second metal seed film 222 are formed at the example dual damascene pattern, and then the second metal seed film 222 is plated by electroplating (as described in connection with FIG. 2C) such that the vias and the trench are substantially filled. In this way, the upper metal pad with the second metal seed film 222 embedded therein, and plural via contacts for connecting the lower metal pad 214 and the upper metal pad are formed.

By using the above example, voids are removed through the processes shown in the processes described in connection with FIGS. 2B, 2C, 2D, and 2E, to form the upper metal pad and plural via contacts.

Also, in disclosed embodiments, a PVD (Physical Vapor Deposition) or an ALD (Atomic Layer Deposition) method can be used to deposit the first and the second metal barrier films 204 and the first and the second metal seed films 206 and 222.

In accordance with example embodiments, the metal plating film can be formed such that the metal pad having plural via contacts is completely filled, and then the insulation film is formed to cause the voids created from the stress between the insulation film and the metal substances to be concentrated at the upper portion of the metal plating film, followed by removing the metal plating film in the void-containing region. As a result, defects between the via contacts and the metal pad are largely prevented, thereby improving bonding force therebetween.

In addition, as the bonding force between the metal pad and the via contacts is improved by removing voids, cracks do not appear on the metal pad during, for example, the future probe test using the metal pad and the packaging process, and defects in a semiconductor device can be minimized.

While the invention has been shown and described with respect to the preferred embodiments, it will be understood by those skilled in the art that various changes and modification may be made without departing from the spirit and scope of the invention as defined in the following claims.

What is claimed is:

1. A method for fabricating a metal pad, comprising the steps of:
selectively etching a wire insulation film formed on a semiconductor substrate to form a predetermined pattern;
depositing a metal film to substantially fill the predetermined pattern;
forming an insulation film on the metal film; and
removing at least a portion of the insulation film and the metal film to expose a surface of the wire insulation film to thereby form a metal pad and via contact.

2. The method of claim 1, wherein depositing a metal film includes the steps of:
forming a barrier metal film and a metal seed film at the pattern; and
plating the metal seed film to substantially fill the pattern.

3. The method of claim 2, wherein the barrier metal film and the metal seed film are formed by a PVD (Physical Vapor Deposition) or an ALD (Atomic Layer Deposition) technique.

4. The method of claim 1, wherein the removing step comprises the steps of:
removing the insulation film by an etching process; and
removing the metal film by a planarization process to expose a top surface of the wire insulation film.

5. The method of claim 1, wherein the metal film comprises copper.

6. The method of claim 1, wherein the insulation film comprises a SiN film or a SiC film.

7. The method of claim 1, further comprising:
performing a heat treatment process after the formation of the insulation film.

8. The method of claim 1, wherein the predetermined pattern is substantially in the form of a dual damascene pattern having plural vias in one trench.
